(19) United States
(12) Patent Application Publication
(10) Pub. No.: US 2015/0171840 A1
(43) Pub. Date: Jun. 18, 2015

(54) LATCH CIRCUIT AND SEMICONDUCTOR INTEGRATED CIRCUIT

(71) Applicant: FUJITSU LIMITED, Kawasaki-shi (JP)

(72) Inventor: Tsutomu Sano, Kawasaki (JP)

(21) Appl. No.: 14/505,524

(22) Filed: Oct. 3, 2014

(30) Foreign Application Priority Data
Dec. 12, 2013 (JP) 2013-257268

(51) Int. Cl. H03K 3/037; H03K 3/013

(52) U.S. Cl. CPC H03K 3/0375; H03K 3/013

(57) ABSTRACT

A latch circuit includes a node configured to store a logic state indicating a value 1 or 0, a detection circuit configured to detect an inversion of the logic state at the node, and a switching circuit configured to switch, when the inversion of the logic state is detected, an output path that outputs the logic state at the node to another path that outputs an original logic state before the inversion of the logic state is detected.

### CROSS-REFERENCE TO RELATED APPLICATIONS

This application is based upon and claims the benefit of priority of the prior Japanese Patent Application No. 2013-257268, filed on Dec. 12, 2013, the entire contents of which are incorporated herein by reference.

### FIELD

The embodiments discussed herein are related to a latch circuit and a semiconductor integrated circuit.

### BACKGROUND

The logic state of data stored in a latch circuit may temporarily become inverted due to noise, such as neutron beam and α-ray from LSI (Large Scale Integrated circuit) materials. As measures against such transient data inversion phenomena (often referred to as “soft errors”), techniques have been proposed to write the inverted logic state of the stored data back to its original logic state. As an example, U.S. Pat. No. 5,570,313 and Japanese Laid-Open Patent Publication No. 5-243916 propose examples of such measures against the soft errors.

However, according to conventional techniques, erroneous data may continue to be output from the latch circuit until the original logic state before the inversion is written back.

### SUMMARY

Accordingly, it is an object in one aspect of the embodiment to provide a latch circuit and a semiconductor integrated circuit which can quickly output a correct logic state even when the stored data is erroneously inverted.

According to one aspect of the present invention, a latch circuit may include a node configured to store a logic state indicating a value 1 or 0; a detection circuit configured to detect an inversion of the logic state at the node; and a switching circuit configured to switch, when the inversion of the logic state is detected, an output path that outputs the logic state at the node to another path that outputs an original logic state before the inversion of the logic is detected.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of an example of a latch circuit;

FIG. 2 is a flow chart for explaining an example of an operation of the latch circuit;

FIG. 3 is a circuit diagram illustrating the configuration of an example of a latch circuit;

FIG. 4 is a diagram illustrating an example of the operation of the latch circuit for a case in which a logic state at a node ND1 is erroneously inverted;

FIG. 5 is a circuit diagram illustrating the configuration of an example of the latch circuit;

FIG. 6 is a circuit diagram illustrating the configuration of an example of the latch circuit;

FIG. 7 is a circuit diagram illustrating the configuration of an example of the latch circuit;

FIG. 8 is a circuit diagram illustrating the configuration of an example of the latch circuit;

FIG. 9 is a circuit diagram illustrating the configuration of an example of the latch circuit; and

FIG. 10 is a circuit diagram illustrating the configuration of an example of a semiconductor integrated circuit.

### DESCRIPTION OF EMBODIMENTS

Preferred embodiments of the present invention will be described with reference to the accompanying drawings.

A description will now be given of the latch circuit and the semiconductor integrated circuit in each embodiment according to the present invention. In the following description, a transistor or a transfer gate that “opens” refers to the transistor or the transfer gate that turns “ON”. In addition, a transistor or a transfer gate that “closes” refers to the transistor or the transfer gate that turns “OFF”. Further, in the drawings, a transistor having a gate with a symbol “o” represents a P-channel MOS (Metal Oxide Semiconductor) transistor, and a transistor having a gate with no symbol “o” represents an N-channel MOS transistor.

<Configuration of Latch Circuit 100>

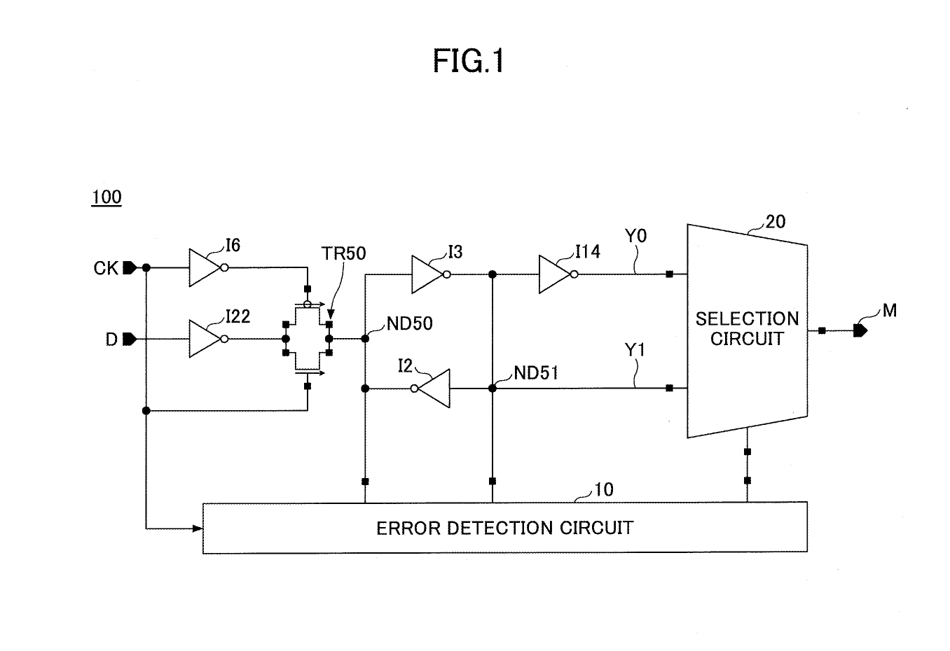

FIG. 1 is a diagram illustrating a configuration of an example of a latch circuit 100. The latch circuit 100 latches a logic state indicating a value 1 or 0 (hereinafter also referred to as “a logic state 1 or 0”) of a data D in synchronism with an input clock CK, and stores the latched logic state (or logic value or logic level) at nodes ND50 and ND51. The latch circuit 100 includes the nodes ND50 and ND51, an error detection circuit 10, and a selection circuit 20.

The nodes ND50 and ND51 form data storing nodes to store the logic state 1 or 0 of the data D. The node ND50 is connected to an input of an inverter I3, and an output of the inverter I3 is connected to the node ND51. The node ND51 is connected to an input of an inverter I2, and an output of the inverter I2 is connected to the node ND50.

When a level of the clock CK makes a transition from 0 (low level) to 1 (high level), a transfer gate TR50 opens. When the transfer gate TR50 opens, the logic state of the data D is written to the nodes ND50 and ND51 via an inverter I22. On the other hand, when the level of the clock CK makes a transition from 1 (high level) to 0 (low level), the transfer gate TR50 closes, and the logic state of the data D written via the inverter I22 is stored at the nodes ND50 and ND51.

The transfer gate TR50 is an example of a switch that includes a P-channel MOS transistor having a gate thereof input with the clock CK via an inverter I6, and an N-channel MOS transistor having a gate thereof input with the clock CK.

In a case in which the transfer gate TR50 is open and the logic state of the data D is 1, the logic state written to the node ND50 is 0, and the logic state written to the node ND51 is 1, that is, the logic state written to the node ND50 and inverted by the inverter I3. Similarly, in a case in which the transfer gate TR50 is open and the logic state of the data D is 0, the logic state written to the node ND50 is 1, and the logic state written to the node ND51 is 0, that is, the logic state written to the node ND50 and inverted by the inverter I3. The logic state 1 or 0 is stored at the nodes ND50 and ND51 when the transfer gate TR50 closes in response to the clock CK.

The error detection circuit 10 is an example of a detection circuit that monitors the logic state of the data D stored at the nodes ND50 and ND51, and detects an inversion of the logic state at the node ND50 or the node ND51. The logic states at the nodes ND50 and ND51 are mutually different in a normal state. The normal state refers to a state in which the logic state at the node ND50 is 0 and the logic state at the node ND51 is 1, or the logic state at the node ND50 is 1 and the logic state at the node ND51 is 0.

However, when the logic state at one of the nodes ND50 and ND51 is erroneously inverted by noise such as α-ray or the like, the logic states at the nodes ND50 and ND51 instantaneously become the same. In other words, when the error detection circuit 10 detects the same logic state at the nodes ND50 and ND51, the error detection circuit 10 can judge that the logic state of one of the nodes ND50 and ND51 is erroneously inverted.

The selection circuit 20 is an example of a switching circuit that switches, when the inversion of the logic state is detected by the error detection circuit 10, an output path that outputs the logic state at the nodes ND50 and ND51 via an output node M to another path that outputs an original logic state before the inversion of the logic state is detected by the error detection circuit 10.

In the following description, the output path that outputs the logic state at the nodes ND50 and ND51 via the output node M will be referred to as an “output path Y”, an output path from the node ND51 and reaching the output node M via an inverter I14 will be referred to as a “path Y0”), and an output path from the node ND51 and reaching the output node M without passing through the inverter I14 will be referred to as a “path Y1”.

For example, it is assumed for the sake of convenience that the selection circuit 20 selects the path Y1 as the output path Y to be used in the normal state in which the logic state 0 is stored at the node ND50 and the logic state 1 is stored at the node ND51, and that an anticipated logic state output from the output node M is the same as the logic state at the node ND51 and is 1.

The selection circuit 20 switches the output path Y from the path Y1 to the path Y0 that is other than the path Y1, when the error detection circuit 10 detects that the logic states are the same (that is, both 0) at the nodes ND50 and ND51 due to the erroneous inversion at the node ND51, for example. In this case, the path Y0 inverts, by the inverter 114, the erroneously inverted logic state 0 at the node ND51, in order to output from the output node M the original logic state 1 before the erroneous inversion at the node ND51 is detected. Accordingly, even when the logic state at the node ND51 is erroneously inverted, the correct logic state 1 matching the anticipated logic state at the output node M can be output quickly from the output node M, by switching the output path Y from the path Y1 to the path Y0.

When the error detection circuit 10 detects the return of the logic state at the node ND51, from the logic state 0 after the erroneous inversion at the node ND51 is detected to the original logic state 1, the selection circuit 20 switches the output path Y from the path Y0 to the original path Y1 before the erroneous inversion at the node ND51 is detected. By switching the output path Y to the original path Y1, the logic state at the node ND51 returns from the erroneously inverted logic state 0 to the original logic state 1 that is to be stored at the node ND51 in the normal state, and it is possible to quickly output from the output node M the correct logic state 1 matching the anticipated logic state at the output node M.

Similarly, the selection circuit 20 switches the output path Y from the path Y1 to the path Y0 that is other than the path Y1, when the error detection circuit 10 detects that the logic states are the same (that is, both 1) at the nodes ND50 and ND51 due to the erroneous inversion at the node ND50, for example. In this case, when the logic state at the node ND50 is erroneously inverted from 0 to 1, the logic state at the node ND51 is erroneously inverted from 1 to 0 by the inverter I3. The path Y0 inverts, by the inverter I14, the erroneously inverted logic state 0 at the node ND50, in order to output from the output node M the original logic state 1 before the erroneous inversion at the node ND51 is detected. Accordingly, even when the logic state at the node ND50 is erroneously inverted, the correct logic state 1 matching the anticipated logic state at the output node M can be output quickly from the output node M, by switching the output path Y from the path Y1 to the path Y0.

When the error detection circuit 10 detects the return of the logic state at the node ND50, from the logic state 1 after the erroneous inversion at the node ND50 is detected to the original logic state 0, the selection circuit 20 switches the output path Y from the path Y0 to the original path Y1 before the erroneous inversion at the node ND50 is detected. By switching the output path Y to the original path Y1, the logic state at the node ND50 returns from the erroneously inverted logic state 1 to the original logic state 0, and the logic state at the node ND51 also returns from the erroneously inverted logic state 0 to the original logic state 1. Hence, by switching the output path Y from the path Y0 to the original path Y1, the logic state at the node ND51 returns from the erroneously inverted logic state 0 to the original logic state 1 that is to be stored at the node ND51 in the normal state, and it is possible to quickly output from the output node M the correct logic state 1 matching the anticipated logic state at the output node M.

For example, the selection circuit 20 may select the path Y1 as the output path Y to be used in the normal state in which the logic state 1 is stored at the node ND50 and the logic state 0 is stored at the node ND51, so that the anticipated logic state output from the output node M is the same as the logic state 0 at the node ND51.

The selection circuit 20 switches the output path Y from the path Y1 to the path Y0 that is other than the path Y1, when the error detection circuit 10 detects that the logic states are the same (that is, both 1) at the nodes ND50 and ND51 due to the erroneous inversion at the node ND51, for example. In this case, the path Y0 inverts, by the inverter 114, the erroneously inverted logic state 1 at the node ND51, in order to output from the output node M the original logic state 0 before the erroneous inversion at the node ND51 is detected. Accordingly, even when the logic state at the node ND51 is erroneously inverted, the correct logic state 0 matching the anticipated logic state at the output node M can be output quickly from the output node M, by switching the output path Y from the path Y1 to the path Y0.

When the error detection circuit 10 detects the return of the logic state at the node ND51, from the logic state 1 after the erroneous inversion at the node ND51 is detected to the original logic state 0, the selection circuit 20 switches the output path Y from the path Y0 to the original path Y1 before the erroneous inversion at the node ND51 is detected. By switching the output path Y to the original path Y1, the logic state at the node ND51 returns from the erroneously inverted logic state 1 to the original logic state 0 that is to be stored at the node ND51 in the normal state, and it is possible to quickly output from the output node M the correct logic state 0 matching the anticipated logic state at the output node M.

Similarly, the selection circuit 20 switches the output path Y from the path Y1 to the path Y0 that is other than the path Y1, when the error detection circuit 10 detects that the logic states are the same (that is, both 0) at the nodes ND50 and ND51 due to the erroneous inversion at the node ND50, for example. In this case, when the logic state at the node ND50 is erroneously inverted from 1 to 0, the logic state at the node ND51 is erroneously inverted from 0 to 1 by the inverter I3. The path Y0 inverts, by the inverter I14, the erroneously inverted logic state 1 at the node ND50, in order to output from the output node M the original logic state 0 before the erroneous inversion at the node ND51 is detected. Accordingly, even when the logic state at the node ND50 is erroneously inverted, the correct logic state 0 matching the anticipated logic state at the output node M can be output quickly from the output node M, by switching the output path Y from the path Y1 to the path Y0.

When the error detection circuit 10 detects the return of the logic state at the node ND50, from the logic state 0 after the erroneous inversion at the node ND50 is detected to the original logic state 1, the selection circuit 20 switches the output path Y from the path Y0 to the original path Y1 before the erroneous inversion at the node ND50 is detected. By switching the output path Y to the original path Y1, the logic state at the node ND50 returns from the erroneously inverted logic state 0 to the original logic state 1, and the logic state at the node ND51 also returns from the erroneously inverted logic state 1 to the original logic state 0. Hence, by switching the output path Y from the path Y0 to the original path Y1, the logic state at the node ND51 returns from the erroneously inverted logic state 1 to the original logic state 0 that is to be stored at the node ND51 in the normal state, and it is possible to quickly output from the output node M the correct logic state 0 matching the anticipated logic state at the output node M.

The selection circuit 20 may select the path Y0 as the output path Y to be used in the normal state, and switch the output path Y from the path Y0 to the path Y1 that is different from the path Y0 when the error detection circuit 10 detects that the logic states at the nodes ND50 and ND51 are the same. By switching the output path Y in this manner, even when the logic state of the node ND50 or the node ND51 is erroneously inverted, it is possible to quickly output from the output node M the correct logic state matching the anticipated logic state at the output node M (for example, an inverted logic state of the logic state at the node ND51 in the normal state).

A case in which the logic states at the nodes ND50 and ND51 instantaneously become the same not only occurs during a data storing time in which the soft error may be generated to erroneously invert the logic state at one of the nodes ND50 and ND51, but also during a data writing time. The data writing time refers to a latch time in which the logic state of the data D in FIG. 1 is written to the nodes ND50 and the node ND51, and the data storing time refers to a time in which the written logic state is stored at the node ND50 and the node ND51.

Accordingly, the detection of the inversion (erroneous inversion or an inversion to return from the erroneously inverted logic state to the original logic state) by the error detection circuit 10 is enabled (or permitted) during the data storing time, and is disabled (or prohibited) during the data writing time. As a result, it is possible to prevent the error detection circuit 10 from erroneously detecting the inversion of the logic state during the data writing time as an erroneous inversion caused by noise, and it is possible to prevent the selection circuit 20 from erroneously switching the output path Y from the current path to another path during the data writing time.

An inversion detecting operation of the error detection circuit 10 to detect the inversion (erroneous inversion or an inversion to return from the erroneously inverted logic state to the original logic state) may preferably be enabled or disabled according to the clock CK that determines the data storing time and the data writing time. In this case, the clock CK that is input to the latch circuit 100 in order to write or store the logic state at the nodes ND50 and ND51 can be used in common as a signal that determines whether to disable or enable the inversion detecting operation of the error detection circuit 10.

For example, by inputting the clock CK to the error detection circuit 10, the error detection circuit 10 can distinguish between the data storing time and the data writing time. In the example illustrated in FIG. 1, the inversion detecting operation of the error detection circuit 10 is enabled during the data storing time in which the level of the clock CK is 0, and the inversion detecting operation of the error detection circuit 10 is disabled during the data writing time in which the level of the clock CK is 1.

A multi-bit error in which the logic states stored at a plurality of nodes are simultaneously inverted due to the soft error, involves a mechanism generated only with respect to a data transition in the same direction. For this reason, the example described above does not take into consideration a case in which the logic states at the nodes ND50 and ND51 are simultaneously inverted.

As measures against the multi-bit error, it is conceivable to include in the latch circuit a duplicate node (or clone node) that stores the same logic state as a data storing node, and to output a majority decision based on outputs of the duplicate node and the data storing node. However, in the case of the latch circuit in this example, no duplicate node exists to store the same logic state as the nodes ND50 and ND51. For this reason, the logic state of the data D can be self-corrected, regardless of whether the error is the multi-bit error or a single-bit error. In addition, in the case of the latch circuit in this example, when the soft error is detected, the correct logic state that is to be output is merely selected and output, and it is unnecessary to use a large amount of time to write back the correct logic state into the data storing node, which would otherwise introduce a large amount of delay.

<Operation of Latch Circuit 100>

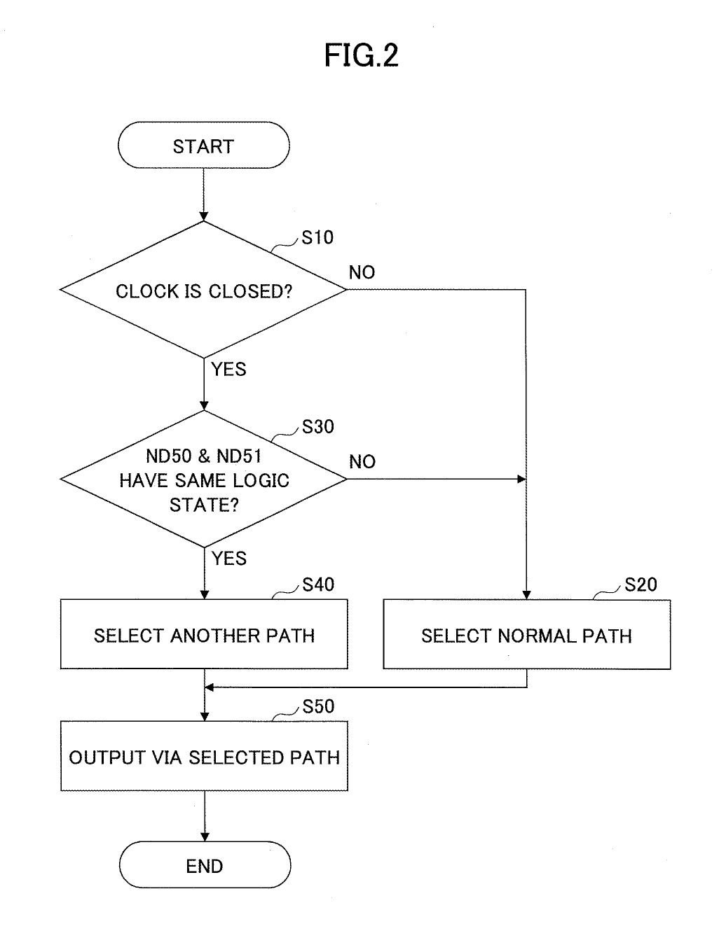

FIG. 2 is a flow chart for explaining an example of an operation of the latch circuit 100.

In step S10, the error detection circuit 10 judges whether the clock CK is closed (that is, whether the current timing is within the data storing time or within the data writing time), based on the level of the input clock CK. When the error detection circuit 10 judges that the clock CK is open (that is, the current timing is within the data writing time) and the judgment result in step S10 is NO, the process advances to step S20.

In step S20, the error detection circuit 10 instructs the selection circuit 20 to set the output path Y to a normal path (path for a case in which the data storing node is used in the normal state). On the other hand, when the error detection circuit 10 judges that the clock CK is closed (that is, the current timing is within the data storing time) and the judgment result in step S10 is YES, the process advances to step S30.

In step S30, the error detection circuit 10 judges whether the logic states at both the nodes ND50 and ND51 are the same. When the error detection circuit 10 judges that the logic states at the nodes ND50 and ND51 are mutually different and the judgment result in step S30 is NO, the process advances to step S20 described above. On the other hand, when the error detection circuit 10 judges that the logic states at the nodes ND50 and ND51 are the same and the judgment result in step S30 is YES, the process advances to step S40.

In step S40, the error detection circuit 10 instructs the selection circuit 20 to set the output path Y to a path (path for a case in which the data storing node is used in the erroneously inverted state) that is different from the normal path.

In step S50, the selection circuit 20 switches the output path Y to a selected path that is set in step S20 or S40, in order to output the logic state stored at the data storing node from the output node M.

<Latch Circuit 101>

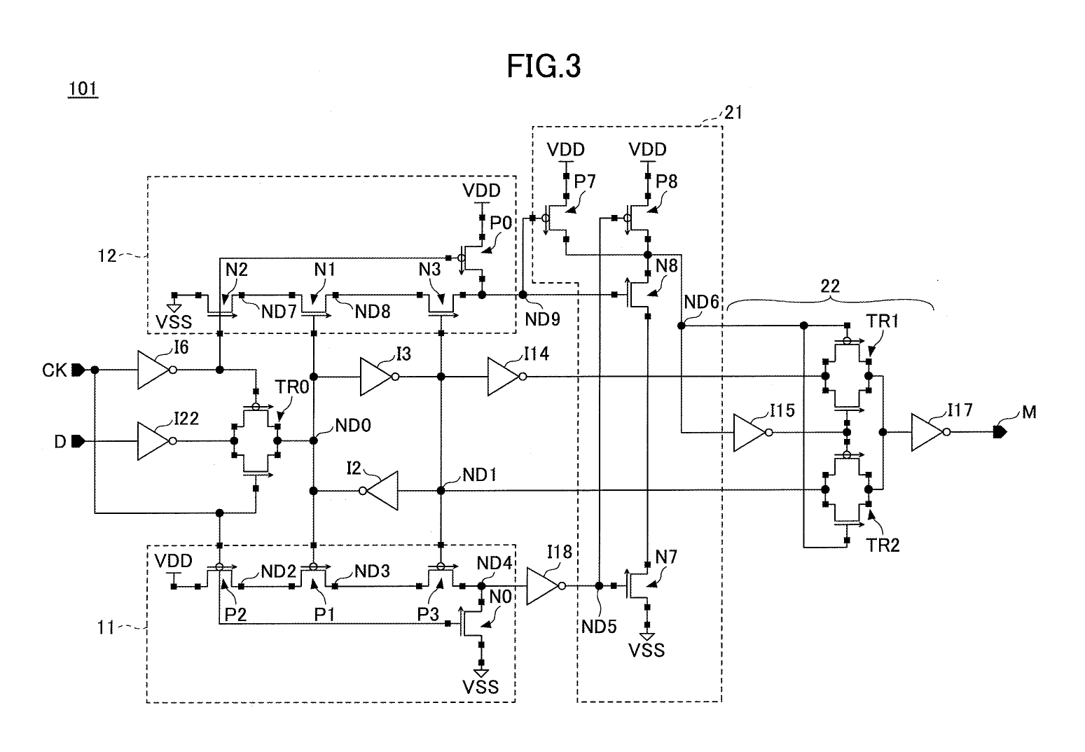

FIG. 3 is a circuit diagram illustrating the configuration of an example of a latch circuit 101 in an embodiment of the latch circuit 100 illustrated in FIG. 1. The latch circuit 101 includes nodes ND0 and ND1 (data storing nodes), error detection circuit 11 and 12, and a selection circuit 22 including a NAND gate (or NAND circuit) 21.

The error detection circuit 11 includes a first equivalence (or match) detector (transistors P1 and P3) to detect that both the nodes ND0 and ND1 have the logic state 0, and a first detecting operation controller (transistor P2) to enable or disable the detecting operation of the first equivalence detector. Similarly, the error detection circuit 12 includes a second equivalence (or match) detector (transistors N1 and N3) to detect that both the nodes ND0 and ND1 have the logic state 1, and a second detecting operation controller (transistor N2) to enable or disable the detecting operation of the second equivalence detector.

The NAND gate 21 instructs the selection circuit 22 to switch an output path that connects the nodes ND0 and ND1 to an output node M, when one of the error detection circuits 11 and 12 detects that both the nodes ND0 and ND1 have the same logic state.

First, a description will be given of a normal latch operation in which the logic state 1 of the data D is written to the latch circuit 101.

When the level of the clock CK changes from 0 to 1 in a state in which the logic state of the data D is 1, a transfer gate TR0 opens, the logic state 0 is written to the node ND0, and the logic state 1 is written to the node ND1 via the inverter I3. When the level of the clock CK is 1, a transistor P0 having a gate input with the clock CK via an inverter I6 opens, and a transistor NO having a gate input with the clock CK opens. For this reason, a logic state at a node ND9 becomes 1 (potential VDD), a logic state at a node ND4 becomes (potential VSS), and a logic state at a node ND5 becomes 1 due to an inverter I18. Accordingly, a transistor N7 and a transistor N8 both open, and a logic state at a node ND6 becomes 0 (potential VSS). Consequently, a transfer gate TR1 opens, and a transfer gate TR2 is closed by an inverter I15.

The transfer gate TR1 passes the inverted logic state at the node ND1 due to the inverter I14, and after passing the transfer gate TR1, the inverted logic state is inverted by an inverter I17. Hence, the logic state 1, that is the same as the logic state written to the node ND1, is output from the output node M.

When the level of the clock CK changes from 1 to 0, the transfer gate TR0 closes, the logic state 0 is stored at the node ND0, and the logic state 1 is stored at the node ND1. When the level of the clock CK changes to 0, the transistor P0 and the transistor NO both close, and thus, the logic state 1 remains stored at the node ND9, and the logic state 1 remains stored at the node ND5. For this reason, the transistor N7 and the transistor N8 both remain open, the transfer gate TR1 also remains open, and the transfer gate TR2 also remains closed. Accordingly, the logic state 1, that is the same as the logic state written to the node ND1, is output from the output node M.

Next, a description will be given of an example of an operation of the latch circuit 101 for a case in which the soft error is generated and the logic state at the node ND1 is inverted thereby.

First, a state similar to that described above is considered in which the logic state of the data D is 1, the logic state 0 is written to and stored at the node ND0, and the logic state 1 is written to and stored at the node ND1. In this state, the anticipated logic state at the output node M is 1, however, the logic state at the output node M becomes 0 when the logic state at the node ND1 is inverted due to the soft error.

During a time in which the level of the clock CK becomes 0 and the transfer gate TR0 is closed, suppose that the logic state at the node ND1 is inverted from 1 to 0 due to the soft error. In this case, the logic states at the nodes ND1 and ND0 both become 0, and the transistors P1 and P3 open simultaneously. In addition, when the level of the clock CK is 0, the transistor P2 opens, the logic states at the nodes ND2, ND3, and ND4 become 1 (potential VDD), and the logic state at the node ND5 is inverted to 0 by the inverter I18. Accordingly, the transistor P8 opens, and the logic state at the node ND6 becomes 1 (potential VDD). For this reason, the transfer gate TR1 closes, and the transfer gate TR2 is opened by the inverter I15.

When the transfer gate TR2 opens, the logic state written to the node ND1 is inverted by the inverter I17, and an inverted logic state of the logic state written to the node ND1 is output from the output node M. Because the logic state at the node ND1 is erroneously inverted from 1 to 0 due to the soft error, the logic state 1 is output from the output node M. Hence, the logic state output from the output node M matches the anticipated logic state at the output node M, even though the soft error is generated.

Next, a description will be given of an example of the operation of the latch circuit 101 for a case in which the soft error is generated and the logic state at the node ND0 is inverted thereby.

First, a state similar to that described above is considered in which the logic state of the data D is 1, the logic state 0 is written to and stored at the node ND0, and the logic state 1 is written to and stored at the node ND1. In this state, the anticipated logic state at the output node M is 1, however, the logic state at the output node M becomes 0 when the logic state at the node ND0 is inverted due to the soft error.

During a time in which the level of the clock CK becomes 0 and the transfer gate TR0 is closed, suppose that the logic state at the node ND0 is inverted from 0 to 1 due to the soft error. In this case, the logic states at the nodes ND1 and ND0 both become 1, and the transistors N1 and N3 open simultaneously. In addition, when the level of the clock CK is 0, the transistor N2 is opened by the inverter I6, and the logic states at the nodes ND7, ND8, and ND9 become 0 (potential VSS). Accordingly, the transistor P7 opens, and the logic state at the node ND6 becomes 1 (potential VDD). For this reason, the transfer gate TR1 closes, and the transfer gate TR2 is opened by the inverter I15.

When the transfer gate TR2 opens, the logic state written to the node ND1 is inverted by the inverter I17, and an inverted logic state of the logic state written to the node ND1 is output from the output node M. Because the logic state at the node ND1 is erroneously inverted from 1 to 0 due to the soft error, the logic state 1 is output from the output node M. Hence, the logic state output from the output node M matches the anticipated logic state at the output node M, even though the soft error is generated.

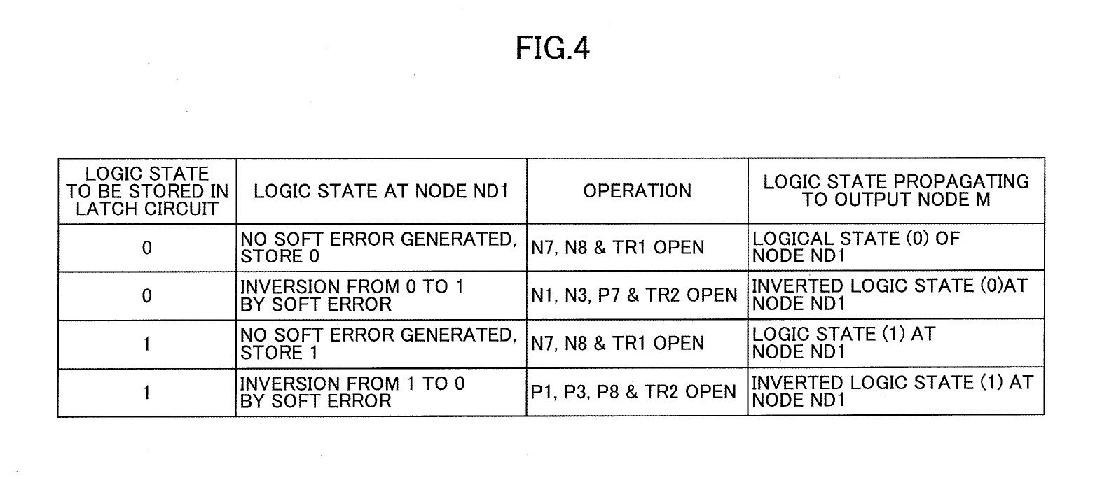

The operation of the latch circuit 101 for a case in which the logic state at the node ND1 is inverted from 0 to 1 due to the soft error, and for a case in which the logic state at the node ND0 is inverted from 1 to 0 due to the soft error, may be understood from the operation described above, which is similar, and a description thereof will be omitted. FIG. 4 is a diagram illustrating an example of the operation of the latch circuit 101 for the case in which the logic state at the node ND1 is erroneously inverted. FIG. 4 illustrates the logic state to be stored in the latch circuit 101, the logic state at the node ND1, the operation of the latch circuit 101, and the logic state propagating to the output node M.

<Latch Circuit 102>

The latch circuit is frequently used in LSI design. For this reason, the latch circuit may be used conveniently in a form of a multi-bit latch circuit capable of latching and storing data having a plurality of bits. In one embodiment, the latch circuit is used in the multi-bit latch circuit, in order to exhibit the effect of quickly outputting the correct logic state even when the logic state is erroneously inverted.

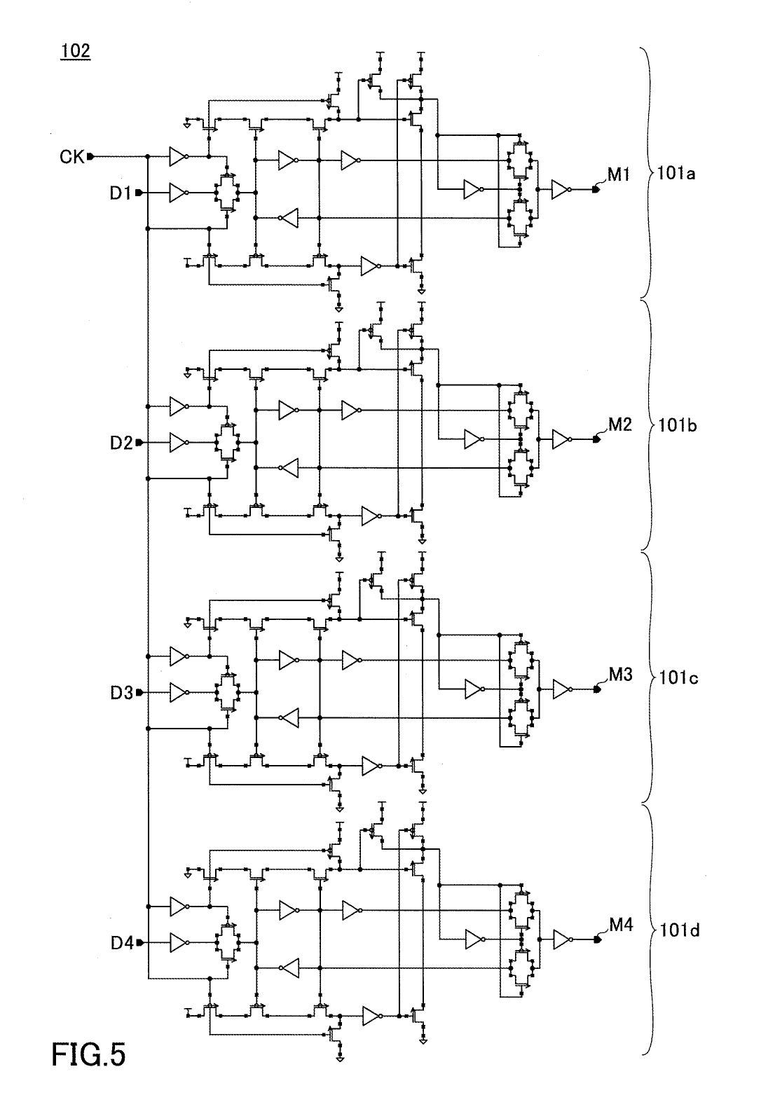

FIG. 5 is a circuit diagram illustrating the configuration of an example of the latch circuit. More particularly, FIG. 5 illustrates the configuration of a latch circuit 102 that is used as the multi-bit latch circuit. The latch circuit 102 includes a plurality of identical latch circuits 101a, 101b, 101c, and 101d having the configuration illustrated in FIG. 3, that are connected in parallel. The latch circuit 102 uses the clock CK in common amongst the latch circuits 101a, 101b, 101c, and 101d. The latch circuits 101a, 101b, 101c, and 101d independently latch and store data D1, D2, D3, and D4, respectively, according to the common clock CK, and independently output the logic states of the stored data from output nodes M1, M2, M3, and M4, respectively.

Although the generation of the multi-bit error must be taken into consideration due to the advances made in the technology of reducing the transistor size, it is difficult to form the conventional latch circuit into the multi-bit latch circuit. The difficulty is caused by the fact that the physical distance between two adjacent bits inevitably becomes short in the case of the multi-bit latch, and that the multi-bit error may be generated in each of the multi-bits and the erroneous data inversion has a high possibility of occurring simultaneously amongst the multi-bits.

However, in one embodiment, the logic state output from the output node can be corrected to the correct logic state, without requiring each bit to depend on another bit. For this reason, even in a state in which the multi-bit may occur, it is possible to form the multi-bit latch circuit with ease.

<Latch Circuit 103>

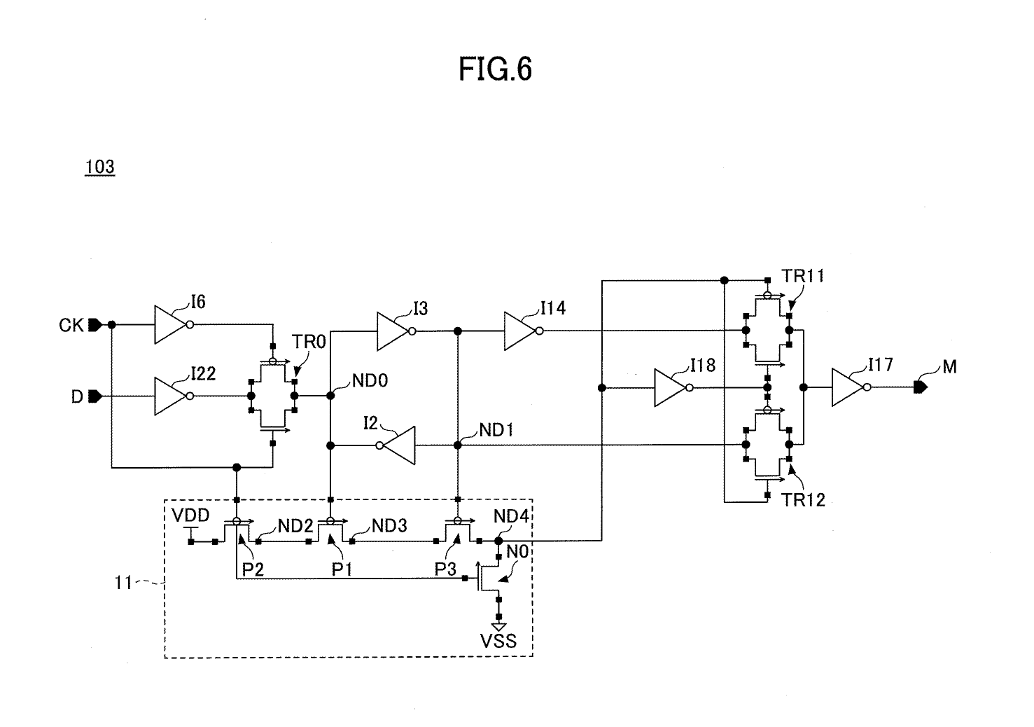

In one embodiment, the logic state output from the output node can be corrected in the case in which the logic state at the data storing node is inverted from 1 to 0, and also in the case in which the logic state at the data storing node is inverted from 0 to 1. However, in a case in which there is a considerable difference between the logic state inverting directions, such as a case in which the probability of the inversion from 0 to 1 is considerably lower than the probability of the inversion from 1 to 0, it may be sufficient for the measures against the soft error, including the multi-bit error, to only consider the inversion of the logic state from 1 to 0. FIG. 6 is a circuit diagram illustrating the configuration of an example of the latch circuit. More particularly, FIG. 6 illustrates the configuration of a latch circuit 103 that only considers the inversion of the logic state from 1 to 0. In this case, the number of transistors forming the latch circuit 103 can be reduced compared to a case in which the inversion of the logic state from 0 to 1 is also considered.

Next, a description will be given of an example of the operation of the latch circuit 103 for a case in which the soft error is generated and the logic state at the node ND1 is inverted thereby.

A state is considered in which the logic state of the data D is 1, the logic state 0 is written to and stored at the node ND0, and the logic state 1 is written to and stored at the node ND1. In this state, the anticipated logic state at the output node M is 1, however, when the logic state at the node ND1 is inverted due to the soft error, the logic state at the output node M becomes 0.

During a time in which the level of the clock CK becomes 0 and the transfer gate TR0 is closed, suppose that the logic state at the node ND1 is inverted from 1 to 0 due to the soft error. In this case, because the logic states at the nodes ND1 and ND0 both become 0, the transistors P1 and P3 simultaneously open. In addition when the level of the clock CK is 0, the transistor P2 opens, and the logic states at the nodes ND2, ND3, and ND4 become 1 (potential VDD). Hence, a transfer gate TR11 closes, and a transfer gate TR12 is opened by the inverter I18.

When the transfer gate TR12 opens, the logic state written to the node ND1 is inverted by the inverter I17, and the inverted logic state of the logic state written to the node ND1 is output from the output node M. In this case, because the logic state at the node ND1 is erroneously inverted from 1 to 0 due to the soft error, the logic state 1 is output from the output node M. Accordingly, the logic state output from the output node M matches the anticipated logic state at the output node M, even though the soft error is generated.

The operation of the latch circuit 103 for a case in which the logic state at the node ND1 is inverted from 0 to 1 due to the soft error, and for a case in which the logic state at the node ND0 is inverted from 1 to 0 or from 0 to 1 due to the soft error, may be understood from the operation described above, which is similar, and a description thereof will be omitted.

<Latch Circuit 104>

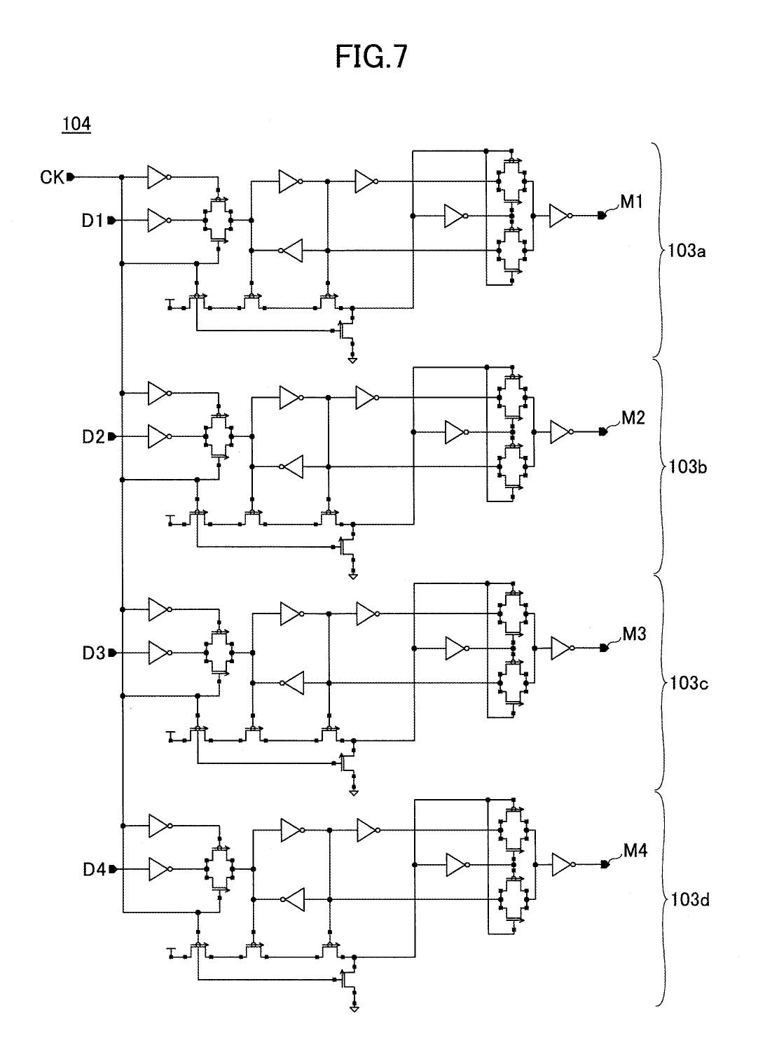

FIG. 7 is a circuit diagram illustrating the configuration of an example of the latch circuit. More particularly, FIG. 7 illustrates the configuration of a latch circuit 104 that is used as the multi-bit latch circuit. The latch circuit 104 includes a plurality of identical latch circuits 103a, 103b, 103c, and 103d having the configuration illustrated in FIG. 6, that are connected in parallel. The latch circuit 104 uses the clock CK in common amongst the latch circuits 103a, 103b, 103c, and 103d. The configuration and effects of the latch circuit 104 illustrated in FIG. 7 are similar to those of the multi-bit latch circuit described above.

<Latch Circuit 105>

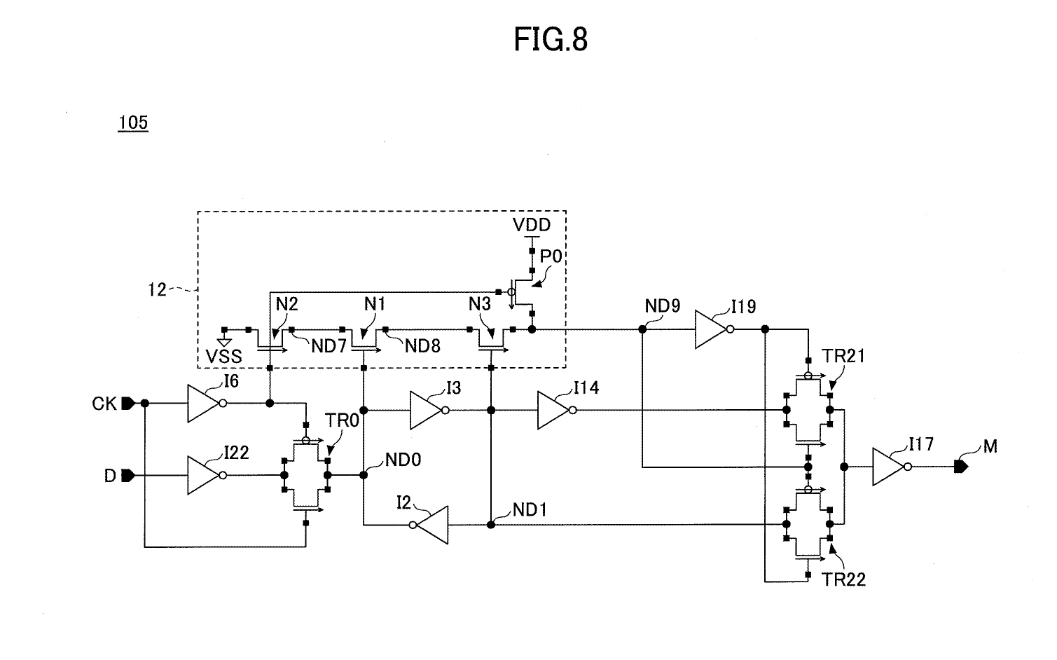

FIG. 8 is a circuit diagram illustrating the configuration of an example of the latch circuit. More particularly, FIG. 8 illustrates the configuration of a latch circuit 105 that only considers the inversion of the logic state from 0 to 1. In this case, the number of transistors forming the latch circuit 105 can be reduced compared to a case in which the inversion of the logic state from 1 to 0 is also considered.

Next, a description will be given of an example of the operation of the latch circuit 105 for a case in which the soft error is generated and the logic state at the node ND1 is inverted thereby.

A state is considered in which the logic state of the data D is 0, the logic state 1 is written to and stored at the node ND0, and the logic state 0 is written to and stored at the node ND1. In this state, the anticipated logic state at the output node M is 0, however, when the logic state at the node ND1 is inverted due to the soft error, the logic state at the output node M becomes 1.

During a time in which the level of the clock CK becomes 0 and the transfer gate TR0 is closed, suppose that the logic state at the node ND1 is inverted from 0 to 1 due to the soft error. In this case, because the logic states at the nodes ND1 and ND0 both become 1, the transistors N1 and N3 simultaneously open. In addition when the level of the clock CK is 0, the transistor N2 opens, and the logic states at the nodes ND7, ND8, and ND9 become 0 (potential VSS). Hence, a transfer gate TR21 is closed by an inverter I19, and a transfer gate TR22 opens.

When the transfer gate TR22 opens, the logic state written to the node ND1 is inverted by the inverter I17, and the inverted logic state of the logic state written to the node ND1 is output from the output node M. In this case, because the logic state at the node ND1 is erroneously inverted from 0 to 1 due to the soft error, the logic state 0 is output from the output node M. Accordingly, the logic state output from the output node M matches the anticipated logic state at the output node M, even though the soft error is generated.

The operation of the latch circuit 105 for a case in which the logic state at the node ND1 is inverted from 1 to 0 due to the soft error, and for a case in which the logic state at the node ND0 is inverted from 1 to 0 or from 0 to 1 due to the soft error, may be understood from the operation described above, which is similar, and a description thereof will be omitted.

<Latch Circuit 106>

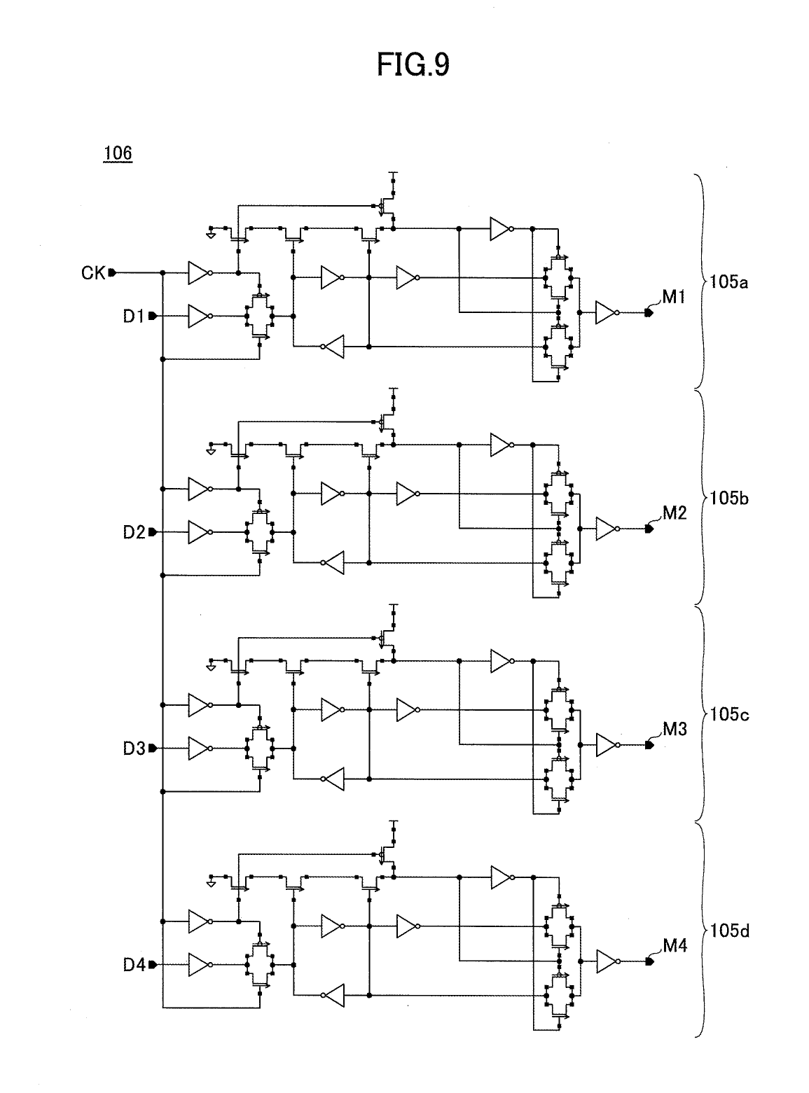

FIG. 9 is a circuit diagram illustrating the configuration of an example of the latch circuit. More particularly, FIG. 9 illustrates the configuration of a latch circuit 106 that is used as the multi-bit latch circuit. The latch circuit 106 includes a plurality of identical latch circuits 105a, 105b, 105c, and 105d having the configuration illustrated in FIG. 8, that are connected in parallel. The latch circuit 106 uses the clock CK in common amongst the latch circuits 105a, 105b, 105c, and 105d. The configuration and effects of the latch circuit 106 illustrated in FIG. 9 are similar to those of the multi-bit latch circuit described above.

<Register File 200>

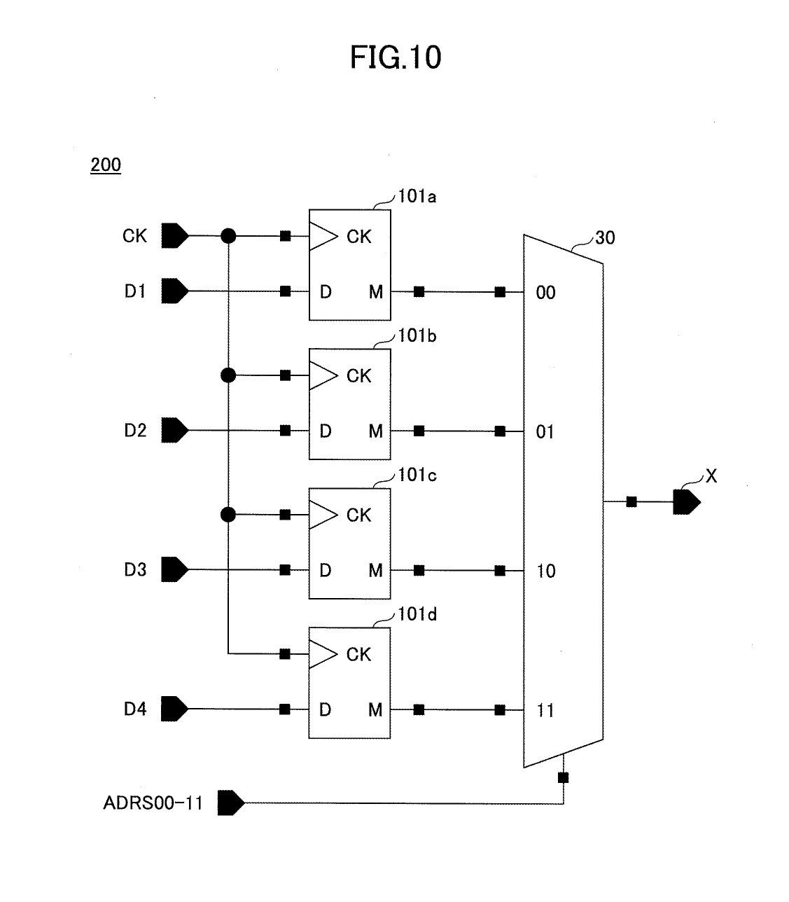

FIG. 10 is a circuit diagram illustrating the configuration of an example of a semiconductor integrated circuit. More particularly, FIG. 10 illustrates the configuration of a register file 200 having a plurality of latch circuits. The register file 200 includes four latch circuits 101a, 101b, 101c, and 101d, and an output circuit 30. The register file 200 is an example of the semiconductor integrated circuit. In order to simplify the description, the register file 200 in this example has an extremely small scale for the sake of convenience.

Each of the latch circuits 101a, 101b, 101c, and 101d may have the configuration of any of the latch circuits in the examples described above. For example, the latch circuit 101, the latch circuit 103, or the latch circuit 105 may be used for each of the latch circuits 101a, 101b, 101c, and 101d. The output circuit 30 outputs, from an output node X, the logic state stored at the data storing node of one of the latch circuits 101a, 101b, 101c, and 101d, according to an instruction signal. In the example illustrated in FIG. 10, the instruction signal is a 2-bit address data ADRS00-11.

A semiconductor memory device, such as the register file formed by the plurality of latch circuits, can have a high reliability by using the latch circuit according to one embodiment. The four latch circuits 101a, 101b, 101c, and 101d are connected in parallel in FIG. 10, in order to form the 1-bit 4-entry register file 200. 1-bit data is stored in the latch circuit at each entry, and the stored data is output from the output node X according to the value of the 2-bit address data ADRS00-11.

As described above, the increase in the integration density of the semiconductor devices is causing an increase in the probability of generating the multi-bit error. For this reason, the multi-bit error may also be generated in the plurality of latch circuits forming the register file. However, when the latch circuit according to one embodiment is used for the register file 200, the output data supplied to the output circuit 30 can be corrected at each latch circuit, without depending on other bits. For this reason, even in a state in which the multi-bit error may occur, it is possible to increase the reliability of the register file 200.

According to each of examples in the embodiment described above, it is possible to quickly output a correct logic state even when the stored data is erroneously inverted.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

For example, the above described configurations of the latch circuits or the circuits (error detection circuit, the selection circuit, or the like) included in the latch circuits are merely examples, and other configurations may be used. In addition, the transistors used in the latch circuit are not limited to the MOS transistors, and other switching elements or devices may be used, such as bi-polar transistors.

Furthermore, the latch circuit in one embodiment is not limited to the use in the semiconductor memory device, such as the register file, and can be used in other semiconductor integrated circuits.

What is claimed is:

1. A latch circuit comprising:
a node configured to store a logic state indicating a value 1 or 0;
a detection circuit configured to detect an inversion of the logic state at the node; and
a switching circuit configured to switch, when the inversion of the logic state is detected, an output path that outputs the logic state at the node to another path that outputs an original logic state before the inversion of the logic state is detected.

2. The latch circuit as claimed in claim 1, wherein the switching circuit switches, when the logic state returns to the original logic state after the inversion of the logic state is detected, the output path that outputs the logic state at the node from the other output path to an original path before the inversion of the logic state is detected.

3. The latch circuit as claimed in claim 2, wherein the output path before the inversion of the logic state is detected outputs a logic state identical to the logic state at the node, and the other output path outputs an inverted logic state of the logic state at the node.

4. The latch circuit as claimed in claim 1, wherein detection of the inversion of the logic state at the node by the detection circuit is enabled during a storing time in which the logic state at the node is stored, and is disabled during a writing time in which the logic state at the node is written.

5. The latch circuit as claimed in claim 4, wherein the detection of the inversion of the logic state at the node by the detection circuit is enabled or disabled in response to a clock that determines the storing time and the writing time.

6. A semiconductor integrated circuit comprising:
a plurality of latch circuits, each including
a node configured to store a logic state indicating a value 1 or 0,
a detection circuit configured to detect an inversion of the logic state at the node, and
a switching circuit configured to switch, when the inversion of the logic state is detected, an output path that outputs the logic state at the node to another path that outputs an original logic state before the inversion of the logic state is detected; and
an output circuit configured to output the logic state stored in one of the plurality of latch circuits in response to an instruction signal.

7. The semiconductor integrated circuit as claimed in claim 6, wherein the switching circuit switches, when the logic state returns to the original logic state after the inversion of the logic state is detected, the output path that outputs the logic state at the node from the other output path to the output path before the inversion of the logic state is detected.

8. The semiconductor integrated circuit as claimed in claim 7, wherein the output path before the inversion of the logic state is detected outputs a logic state identical to the logic state at the node, and the other output path outputs an inverted logic state of the logic state at the node.

9. The semiconductor integrated circuit as claimed in claim 6, wherein detection of the inversion of the logic state at the node by the detection circuit is enabled during a storing time in which the logic state at the node is stored, and is disabled during a writing time in which the logic state at the node is written.

10. The semiconductor integrated circuit as claimed in claim 9, wherein the detection of the inversion of the logic state at the node by the detection circuit is enabled or disabled in response to a clock that determines the storing time and the writing time.
